(19) United States
(12) Patent Application Publication
(10) Pub. No.: US 2013/0248799 A1
(43) Pub. Date: Sep. 26, 2013

(54) VARIABLE RESISTANCE MEMORY DEVICE AND METHOD FOR FABRICATING THE SAME

(71) Applicant: SK HYNIX INC., Gyeonggi-do (KR)

(72) Inventors: Seok-Pyo SONG, Gyeonggi-do (KR); Jin-Won PARK, Gyeonggi-do (KR); Jae-Yun YI, Gyeonggi-do (KR); Sang-Keum LEE, Gyeonggi-do (KR); Dong-Hee SON, Gyeonggi-do (KR)

(73) Assignee: SK hynix Inc., Gyeonggi-do (KR)

(21) Appl. No.: 13/736,675

(22) Filed: Jan. 8, 2013

(30) Foreign Application Priority Data
Mar. 26, 2012 (KR) 10-2012-0030516

(51) Int. Cl. H01L 45/00

(52) U.S. Cl. CPC H01L 45/12
USPC 257/2

(57) ABSTRACT

A variable resistance memory device includes first electrodes, dielectric layer patterns vertically projecting from the first electrodes, variable resistance layer patterns surrounding side surfaces of the dielectric layer patterns and connected with the first electrodes, and second electrodes formed over the dielectric layer patterns and connected with the variable resistance layer patterns.

### CROSS-REFERENCE TO RELATED APPLICATIONS

The present application claims priority of Korean Patent Application No. 10-2012-0030516, filed on Mar. 26, 2012, which is incorporated herein by reference in its entirety.

### BACKGROUND

1. Field

Exemplary embodiments of the present invention relate to a variable resistance memory device and a method for fabricating the same, and more particularly, to a variable resistance memory device which includes a variable resistance layer interposed between electrodes and a method for fabricating the same.

2. Description of the Related Art

A variable resistance memory device refers to a device which stores data, based on such a characteristic that changes resistance according to an external stimulus and switches two different resistance states, and includes an ReRAM (resistive random access memory), a PCRAM (phase change RAM) and an SU-RAM (spin transfer torque-RAM). The variable resistance memory device has been actively researched since it can be formed to a simple structure and has various excellent properties such as nonvolatiliity and so forth.

Among variable resistance memory devices, the ReRAM has a structure which includes a variable resistance layer formed of a variable resistance substance, for example, a perovskite-based substance or a transition metal oxide and electrodes formed over and under the variable resistance layer. According to a voltage applied to an electrode, filament-type current paths are created or vanished in the variable resistance layer. The variable resistance layer becomes a low resistance state when the filament-type current paths are created and becomes a high resistance state when the filament-type current paths are vanished.

Since the variable resistance memory device has a structure in which electrodes and a variable resistance layer are connected in series, in order to increase a resistance difference between a high resistance state and a low resistance state, the resistance of the variable resistance layer should be remarkably larger than the resistance of the electrodes. In this regard, the resistance of the variable resistance layer may be increased by reducing the sectional area of the variable resistance layer and enlarging the length of the variable resistance layer to make an aspect ratio large. Consequently, the operating voltage of memory cells may be decreased and the number of memory cells per unit block may be increased to raise the degree of integration of the variable resistance memory device.

FIGS. 1A to 1E are cross-sectional views explaining a conventional variable resistance memory device and a method for fabricating the same.

Referring to FIG. 1A, after an interlayer dielectric layer 20 is formed on a substrate 10 with a predetermined underlying structure (not shown) and contact holes H to expose the substrate 10 are defined by selectively etching the interlayer dielectric layer 20, contact plugs 30 are formed in the contact holes H.

Referring to FIG. 1B, after sequentially forming a conductive layer 40 for first electrodes, a variable resistance layer 50, a conductive layer 60 for second electrodes and a hard mask layer 70 on the interlayer dielectric layer 20 and the contact plugs 30, a photoresist pattern 80 is formed on the hard mask layer 70 to cover regions where memory cells are to be formed.

Referring to FIG. 1C, by etching the hard mask layer 70, the conductive layer 60 for second electrodes, the variable resistance layer 50 and the first conductive layer 40 for first electrodes using the photoresist pattern 80 as an etch mask, hard mask patterns 70A, second electrodes 60A, variable resistance layer patterns 50A and first electrodes 40A are formed.

However, in the conventional art, it is substantially difficult to obtain the vertically etched profile as shown in FIG. 1C. In this regard, in the case where the variable resistance layer 50 is formed of a substance which is not etched well, the etched profile of the variable resistance layer 50 has a positive slope as shown in FIG. 1D, and, in the case where the variable resistance layer 50 is formed of a substance which is etched well, the etched profile of the variable resistance layer 50 has a negative slope as shown in FIG. 1E.

In particular, when the etched profile of the variable resistance layer 50 has a positive slope, the second electrodes 60A are excessively etched when compared to the first electrodes 40A, and when the etched profile of the variable resistance layer 50 has a negative slope, the variable resistance layer 50 is non-uniformly etched to increase the resistance dispersion of memory cells. According to this fact, not only it is difficult to enlarge the aspect ratio of the variable resistance layer 50, but also the variable resistance layer 50 is likely to be damaged in an etching process to be degraded in the properties thereof.

### SUMMARY

Embodiments of the present invention are directed to a variable resistance memory device which can form variable resistance layer patterns with a high aspect ratio, thereby improving the characteristics of a variable resistance memory device and increasing the number of memory cells per unit block to raise the degree of integration, and, a method for fabricating the same.

In accordance with an embodiment of the present invention, a variable resistance memory device includes: first electrodes; dielectric layer patterns vertically projecting from the first electrodes; variable resistance layer patterns surrounding side surfaces of the dielectric layer patterns and connected with the first electrodes; and second electrodes formed over the dielectric layer patterns and connected with the variable resistance layer patterns.

In accordance with another embodiment of the present invention, a variable resistance memory device includes: first electrodes; dielectric layer patterns vertically projecting from the first electrodes and having shapes of lines which extend in one direction; variable resistance layer patterns disposed such that a pair of variable resistance layer patterns are arranged in parallel with each other and in both sides of each dielectric layer pattern, and connected with the first electrodes; and second electrodes formed over the dielectric layer patterns and connected with the variable resistance layer patterns.

In accordance with yet another embodiment of the present invention, a method for fabricating a variable resistance memory device includes: forming structures with shapes of pillars, in which first electrodes, dielectric layer patterns and second electrodes are sequentially stacked; partially etching side surfaces of the dielectric layer patterns; and forming variable resistance layer patterns to contact the side surfaces of the dielectric layer patterns and be connected with the first and second electrodes.

According to the embodiments of the present invention, since variable resistance layer patterns with a high aspect ratio are formed, the characteristics of a variable resistance memory device may be improved, and the number of memory cells per unit block may be increased to raise the degree of integration.

### BRIEF DESCRIPTION OF THE DRAWINGS

FIGS. 1A to 1E are cross-sectional views explaining conventional variable resistance memory device and a method for fabricating the same.

FIGS. 2A to 2F are cross-sectional views explaining a variable resistance memory device in accordance with a first embodiment of the present invention and a method for fabricating the same.

FIGS. 3A to 3H are cross-sectional views explaining a variable resistance memory device in accordance with a second embodiment of the present invention and a method for fabricating the same.

FIG. 4 is a perspective view illustrating a cross point cell array structure.

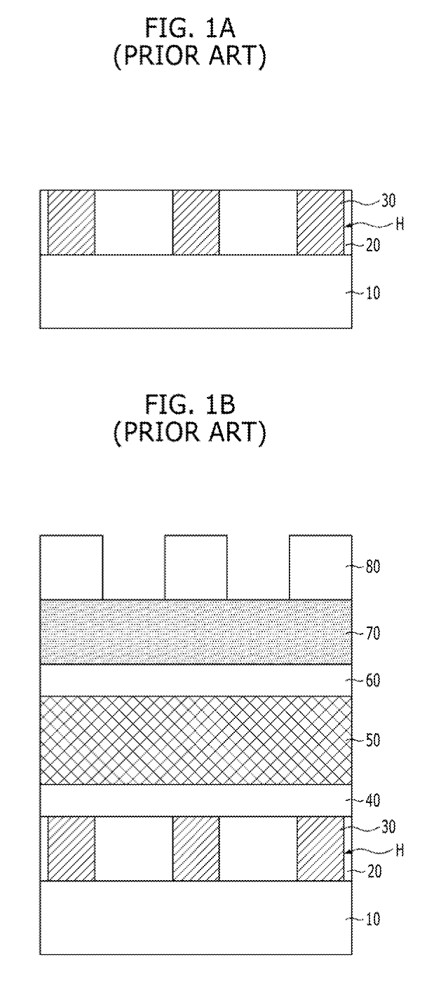

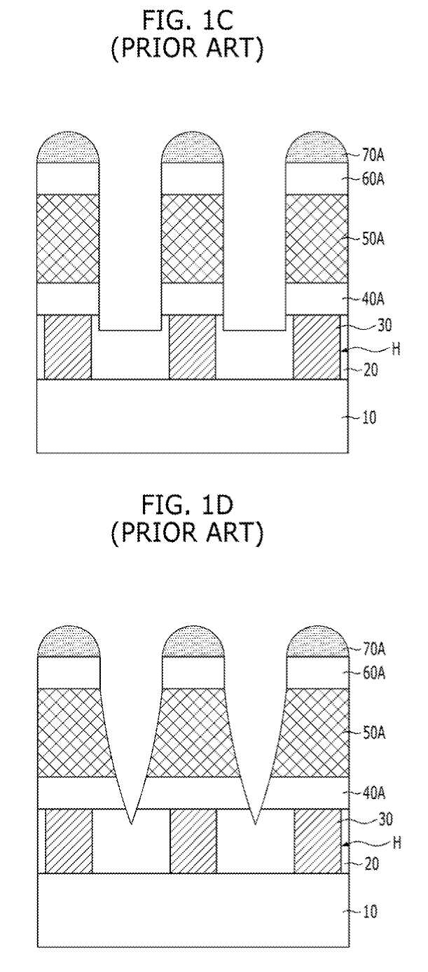

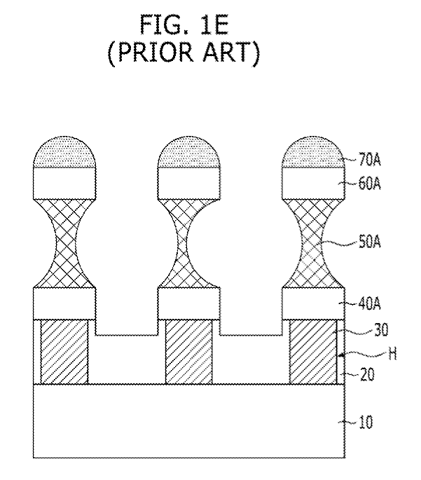

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some stances, proportions may have been exaggerated in order to clearly illustrate features of the embodiments. When a first layer is referred to as being on a second layer or on a substrate, it not only refers to a case where the first layer is formed directly on the second layer or the substrate but also a case where a third layer exists between the first layer and the second layer or the substrate.

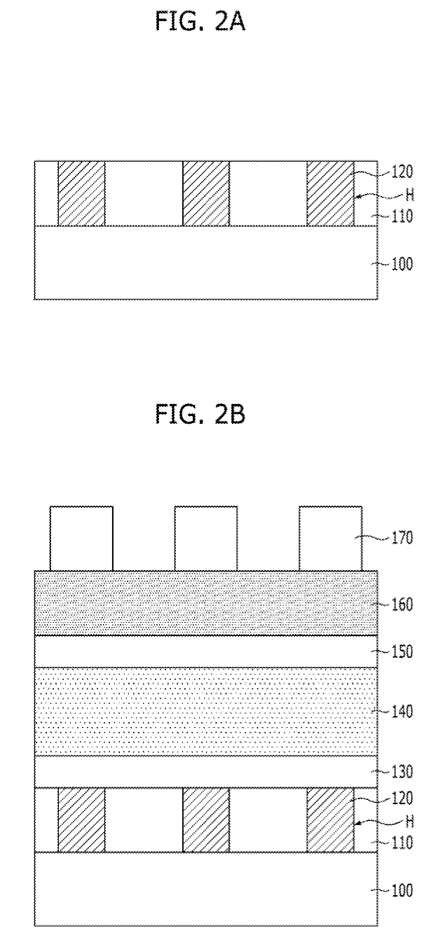

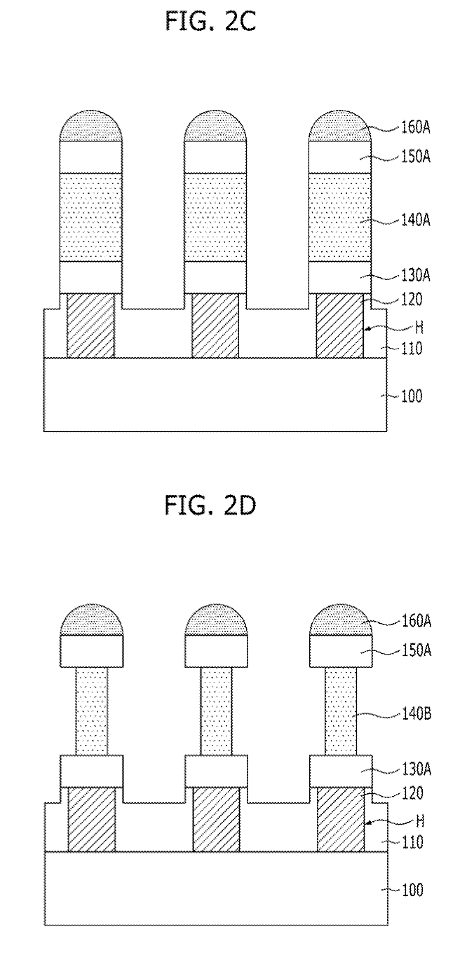

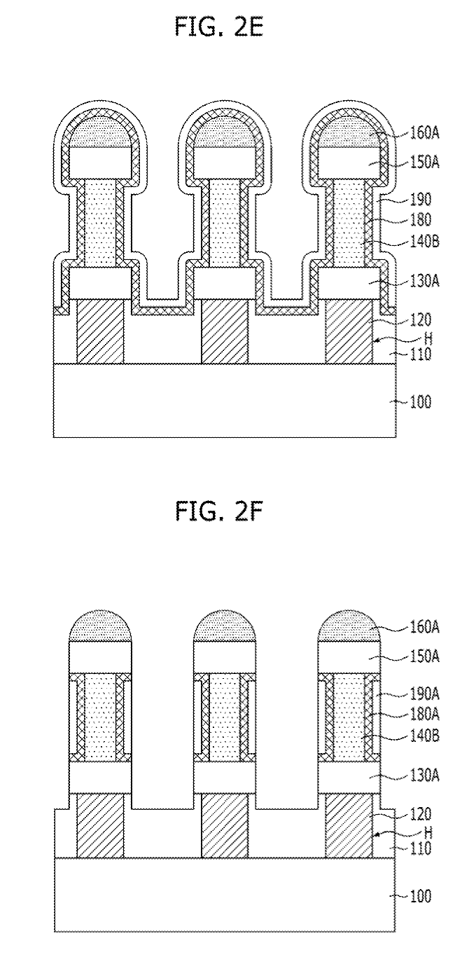

FIGS. 2A to 2F are cross-sectional views explaining a variable resistance memory device in accordance with a first embodiment of the present invention and a method for fabricating the same. In particular, FIG. 2F is a cross-sectional view illustrating the variable resistance memory device in accordance with the first embodiment of the present invention, and FIGS. 2A to 2E are cross-sectional views illustrating the processes of a method for fabricating the variable resistance memory device of FIG. 2F.

Referring to FIG. 2A, an interlayer dielectric layer 110 is formed on a substrate 100 with a predetermined underlying structure (not shown). The interlayer dielectric layer 110 may include at least any one of oxide-based substances, for example, a silicon oxide (SiO₂), TEOS (tetra ethyl ortho silicate), BPSG (boron phosphorus silicate glass), BSG (boron silicate glass), PSG (phosphorus silicate glass), FSG (fluorinated silicate glass) and SOG (spin-on-glass). In the meantime, while not shown in the drawing, the substrate 100 may include peripheral circuits for driving a variable resistance memory device.

After defining contact holes H to expose the substrate 100 by selectively etching the interlayer dielectric layer 110, contact plugs 120 are formed in the contact holes H.

A plurality of contact holes H may be arranged in the form of a matrix when viewed from the top. The contact plugs 120 may be formed by depositing a conductive substance, for example, doped polysilicon, a metal or a metal nitride, to a thickness filling the contact holes H and performing a planarization process such as chemical mechanical polishing (CMP) until the upper surface of the interlayer dielectric layer 110 is exposed.

Referring to FIG. 2B, a conductive layer 130 for first electrodes, a dielectric layer 140, a conductive layer 150 for second electrodes and a hard mask layer 160 are sequentially formed on the interlayer dielectric layer 110 and the contact plugs 120.

The conductive layers 130 and 150 for first and second electrodes may include at least any one of conductive substances, for example, metals such as platinum (Pt), gold (Au), silver (Ag), tungsten (W), aluminum (Al), ruthenium (Ru), iridium (Ir), titanium (Ti), hafnium (Hf), zirconium (Zr), cobalt (Co), nickel (Ni), chrome (Cr) and copper (Cu), metal nitrides such as a titanium nitride (TiN), a tantalum nitride (TaN), a tungsten nitride (WN) a titanium aluminum nitride (TiAlN) and a titanium silicon nitride (TiSiN), and metal oxides such as a ruthenium oxide (RuOₓ), an iridium oxide (IrOₓ) and an indium tin oxide (ITO).

The dielectric layer 140 is formed of a substance which allows anisotropic etching to be easily performed to obtain a vertical etched profile, and may include, for example, at least any one selected from the group consisting of an oxide-based or nitride-based substance and polysilicon. In particular, in order to allow variable resistance layer patterns which will be described later, to have a large aspect ratio, the dielectric layer 140 may be formed thicker than the conductive layers 130 and 150 for first and second electrodes.

The hard mask layer 160 may include at least any one selected from the group consisting of an amorphous carbon layer (ACL), a silicon oxynitride (SiON) and a bottom anti-reflective coating (BARC).

Then, a photoresist pattern 170 is formed on the hard mask layer 160 to cover regions where pillar-shaped structures, that is, memory cells are to be formed. The photoresist pattern 170 may include photosensitive polymer mainly including carbon.

Referring to FIG. 2C, by anisotropically etching the hard r ask layer 160, the conductive layer 150 for second electrodes, the dielectric layer 140 and the conductive layer 130 for first electrodes using the photoresist pattern 170 as an etch mask, pillar-shaped structures, in which first electrodes 130A, primary dielectric layer patterns 140A, second electrodes 150A and hard mask patterns 160A are sequentially stacked, are formed. The upper surfaces of the hard mask patterns 160A may have rounded contours.

The pillar-shaped structures may have vertical etched profiles and island-like shapes which are separated for respective memory cells. A plurality of pillar-shaped structures may be arranged in the form of a matrix when viewed from the top. As a result of the process, the interlayer dielectric layer 110 may be partially etched, and a cleaning process for removing etching byproducts may be additionally performed.

Referring to FIG. 2D the side surfaces of the primary dielectric layer patterns 140A are etched to be recessed.

In order to recess the primary dielectric layer patterns 140A, for example, an isotropic wet or dry etching process using an etching selectivity with respect to the first and second electrodes 130A and 150A may be performed. The primary dielectric layer patterns 140A recessed as a result of this process will be referred to as secondary dielectric layer patterns 140B. The secondary dielectric layer patterns 140B may have an aspect ratio larger than the first and second electrodes 130A and 150A.

Referring to FIG. 2E, a variable resistance layer 180 and a passivation layer 190 are sequentially formed on the entire surface of the substrate 100 formed with the pillar-shaped structures. The variable resistance layer 180 may include a substance of which electrical resistance changes by migration of oxygen vacancies or ions or phase change, and may be formed to a thickness of 2 nm to 20 nm.

A substance of which electrical resistance changes by migration of oxygen vacancies or ions includes a perovskite-based substance such as STO (SrTiO₃), BTO (BaTiO₃) and PCMO (Pr^{1-x}CaₓMnO₃) and a binary oxide including a transition metal oxide (TMO) such as a titanium oxide (TiO₂, Ti₄O₇), a hafnium oxide (HfO₂), a zirconium oxide (ZrO₂), an aluminum oxide (Al₂O₃), a tantalum oxide (Ta₂O₅), a niobium oxide (Nb₂O₅), a cobalt oxide (Co₃O₄), a nickel oxide (NiO), a tungsten oxide (WO₃) and a lanthanum oxide (La₂O₃). Also, a substance of which electrical resistance changes by phase change includes a substance which is converted into a crystalline state or an amorphous state by heat, for example, a chalcogenide-based substance such as GST (GeSbTe) in which germanium, antimony and tellurium are mixed at predetermined ratios.

The passivation layer 190 is to prevent the variable resistance layer 180 from being damaged in a blanket etching process which will be described below, and may be formed by conformally depositing at least any one of an oxide-based substance, a nitride-based substance and a carbide-based substance.

Referring to FIG. 2F, by blanket-etching the resultant structure formed with the passivation layer 190, variable resistance layer patterns 180A which surround the side surfaces of the secondary dielectric layer patterns 140B and are connected with the first and second electrodes 130A and 150A are formed. The passivation layer 190 remaining on the side surfaces of the variable resistance layer patterns 180A as a result of this process will be referred to as passivation layer patterns 190A.

By the fabrication method as described above, the variable resistance memory device in accordance with the first embodiment of the present invention as shown in FIG. 2F may be fabricated.

Referring to FIG. 2F, the variable resistance memory device in accordance with the first embodiment of the present invention may include the first electrodes 130A, the secondary dielectric layer patterns 140B which have pillar-like shapes vertically projecting from the first electrodes 130A, the variable resistance layer patterns 180A which surround the side surfaces of the secondary dielectric layer patterns 140B and are connected with the first electrodes 130A, the second electrodes 150A which are positioned on the secondary dielectric layer patterns 140B and are connected with the variable resistance layer patterns 180A, and the passivation layer patterns 190A which surround the side surfaces of the variable resistance layer patterns 180A.

The secondary dielectric layer patterns 140B may have island-like shapes which are separated for respective memory cells. The secondary dielectric layer patterns 140B may have an aspect ratio larger than the first and second electrodes 130A and 150A and may include at least any one selected from the group consisting of an oxide-based or nitride-based substance and polysilicon. The first and second electrodes 130A and 150A may project sideward out of the secondary dielectric layer patterns 140B.

The variable resistance layer patterns 180A may be formed even on the upper surfaces of the projecting first electrodes 130A and on the lower surfaces of the projecting second electrodes 150A such that portions of the variable resistance layer patterns 180A overlapping with the first and second electrodes 130A and 150A project perpendicularly from the side surfaces of the secondary dielectric layer patterns 140B. The variable resistance layer patterns 180A may include a substance of which electrical resistance changes by migration of oxygen vacancies or ions or phase change.

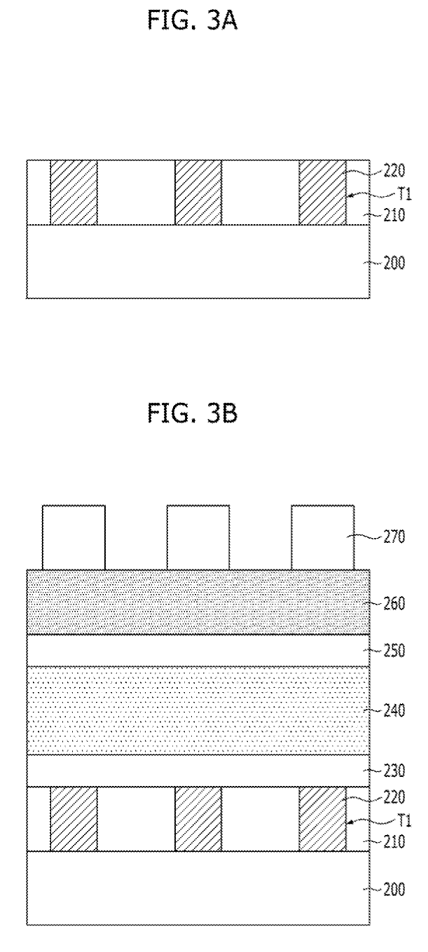

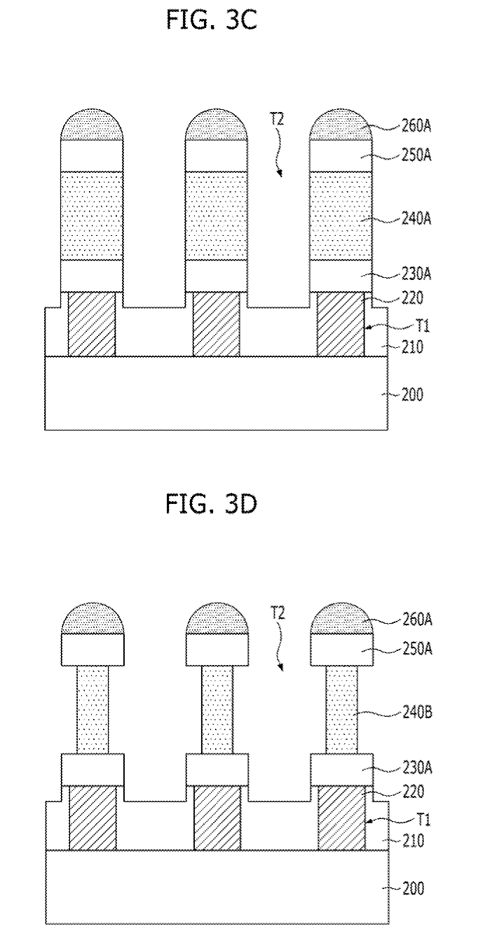

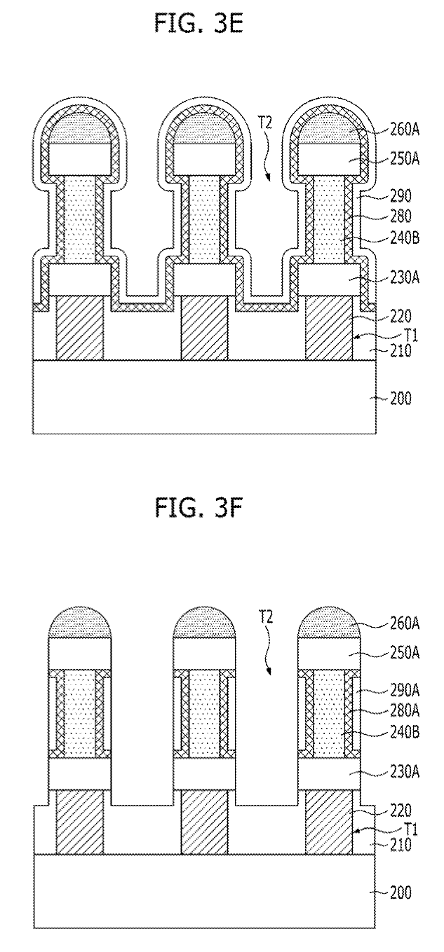

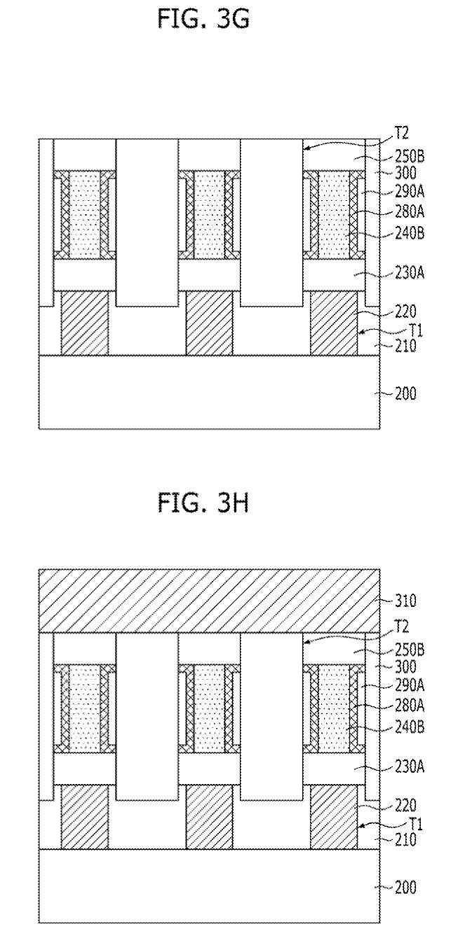

FIGS. 3A to 3H are cross-sectional views explaining a variable resistance memory device in accordance with a second embodiment of the present invention and a method for fabricating the same. In describing the present embodiment, detailed descriptions for substantially the same component parts as the aforementioned first embodiment will be omitted.

Referring to FIG. 3A, a first interlayer dielectric layer 210 is formed on a substrate 200 with a predetermined underlying structure (not shown). The first interlayer dielectric layer 210 may include at least any one of oxide-based substances, for example, a silicon oxide (SiO₂), TEOS, BPSG, BSG, PSG, FSG and SOG.

After defining first trenches T1 to expose the substrate 200 by selectively etching the first interlayer dielectric layer 210, first conductive lines 220 are formed in the first trenches T1.

The first trenches T1 may have the shapes of slits which extend in a direction crossing with the cross-section of the drawing, and a plurality of first trenches T1 may be arranged in parallel to one another. The first conductive lines 220 may be formed by depositing a conductive substance, for example, doped polysilicon, a metal or a metal nitride, to a thickness filling the first trenches T1 and performing a planarization process such as chemical mechanical polishing (CMP) until the upper surface of the first interlayer dielectric layer 210 is exposed.

Referring to FIG. 3B, a conductive layer 230 for first electrodes, a dielectric layer 240, a conductive layer 250 for second electrodes and a hard mask layer 260 are sequentially formed on the first interlayer dielectric layer 210 and the first conductive lines 220. Since the first conductive lines 220 may serve actually as bottom electrodes, the conductive layer 230 for first electrodes may be omitted.

The conductive layers 230 and 250 for first and second electrodes may include at least any one of conductive substances, for example, a metal, a metal nitride and a metal oxide. The dielectric layer 240 is formed of a substance which allows anisotropic etching to be easily performed to obtain a vertical etched profile, and may include, for example, at least any one selected from the group consisting of an oxide-based or nitride-based substance and polysilicon. The hard mask layer 260 may include at least any one selected from the group consisting of an amorphous carbon layer (ACL), a silicon oxynitride (SiON) and a bottom anti-reflective coating (BARC).

Then, a photoresist pattern 270 is formed on the hard mask layer 260 to cover regions where the first conductive lines 220 are formed. The photoresist pattern 270 may include photosensitive polymer mainly including carbon.

Referring to FIG. 3C, by anisotropically etching the hard mask layer 260, the conductive layer 250 for second electrodes, the dielectric layer 240 and the conductive layer 230 for first electrodes using the photoresist pattern 270 as an etch mask, second trenches T2 are defined. The second trenches T2 may have the shapes of slits which extend in the same direction as the first trenches T1, and a plurality of second trenches T2 may be arranged in parallel to one another.

As a result of this process, structures in which first electrodes 230A, primary dielectric layer patterns 240A, second electrodes 250A and hard mask patterns 260A are sequentially stacked are formed. The stacked structures may have vertical etched profiles, and the upper surfaces of the hard mask patterns 260A may have rounded contours.

Referring to FIG. 3D, the side surfaces of the primary dielectric layer patterns 240A are etched to be recessed.

In order to recess the primary dielectric layer patterns 240A, an isotropic wet or dry etching process using an etching selectivity with respect to the first and second electrodes 230A and 250A may be performed. The primary dielectric layer patterns 240A recessed as a result of this process will be referred to as secondary dielectric layer patterns 240B. The secondary dielectric layer patterns 240B may have an aspect ratio larger than the first and second electrodes 230A and 250A.

Referring to FIG. 3E, a variable resistance layer 280 and a passivation layer 290 are sequentially formed on the entire surface of the substrate 200 formed with the stacked structures.

The variable resistance layer 280 may include a binary oxide including a transition metal oxide (TMO) or a perovskite-based substance of which electrical resistance changes by migration of oxygen vacancies or ions or a chalcogenide-based substance of which electrical resistance changes by phase change. The passivation layer 290 is to prevent the variable resistance layer 280 from being damaged in a blanket etching process which will be described below, and may be formed by conformally depositing at least any one of an oxide-based substance, a nitride-based substance and a carbide-based substance.

Referring to FIG. 3F, by blanket-etching the resultant structure formed with the passivation layer 290, variable resistance layer patterns 280A which contacts the side surfaces of the secondary dielectric layer patterns 240B and are connected with the first and second electrodes 230A and 250A are formed.

A pair of variable resistance layer patterns 280A may be arranged in parallel with each other, with each secondary dielectric layer pattern 240E in the form of a line extending in the direction crossing with the cross-section of the drawing. The passivation layer 290 remaining on the side surfaces of the variable resistance layer patterns 280A as a result of this process will be referred to as passivation layer patterns 290A.

Referring to FIG. 3G, a second interlayer dielectric layer 300 is formed in the second trenches T2. The second interlayer dielectric layer 300 may be formed by depositing a dielectric substance, for example, an oxide-based substance, to a thickness filling the second trenches T2 and performing a planarization process such as chemical mechanical polishing (CMP) until the upper surface of the second electrodes 250A are exposed.

Next, after forming mask patterns on the second electrodes 250A and the second interlayer dielectric layer 300 to have the form of lines extending in a direction crossing with the second electrodes 250A, second electrode patterns 250E are formed by etching the second electrodes 250A using the mask patterns as etch masks.

A plurality of mask patterns may be arranged parallel to one another, and as a result of this process, the second interlayer dielectric layer 300 may be partially etched. The second electrode patterns 250B may have island-like shapes which are separated for respective memory cells, and a plurality of second electrode patterns 250B may be arranged in the form of a matrix when viewed from the top.

Referring to FIG. 3H, second conductive lines 310 are formed to be connected with the second electrode patterns 2508 arranged in lines and extend in a direction crossing with the first conductive lines 220. A plurality of second conductive lines 310 may be arranged parallel to one another.

The second conductive lines 310 may be formed by forming a third interlayer dielectric layer (not shown) on the second electrode patterns 250B and the second interlayer dielectric layer 300, selectively etching the third interlayer dielectric layer to provide spaces for forming the second conductive lines 310, and filling a conductive substance such as doped polysilicon, a metal or a metal nitride in the spaces.

The second embodiment is distinguished from the first embodiment in that a pair of variable resistance layer patterns 280A are arranged in parallel with each other with each secondary dielectric layer pattern 240B in the form of a line interposed therebetween and the first conductive lines 220 connected with the first electrodes 230A and extending in one direction and the second conductive lines 310 connected with the second electrode patterns 250B and extending in the direction crossing with the first conductive lines 220 are formed.

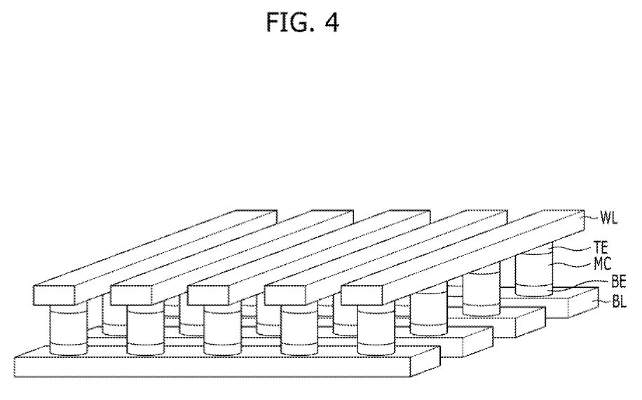

FIG. 4 is a perspective view illustrating a cross point cell array structure.

Referring to FIG. 4, the variable resistance memory device in accordance with the embodiments of the present invention may be formed to have a cross point cell array structure. The cross point cell array structure refers to a structure in which memory cells MC are disposed at crossing points between a plurality of bit lines BL parallel to one another and a plurality of word lines WL crossing with the bit lines BL and parallel to one another, and selection elements (not shown), for example, transistors or diodes may be connected to the top parts or bottom parts of the respective memory cells MC.

The memory cells MC may include variable resistance layer patterns of which resistance changes according to an applied voltage or current to be switched between at least two resistance states. The bottom parts of the memory cells MC may be connected with the bit lines BL through bottom electrodes BE, and the top parts of the memory cells MC may be connected with the word lines WL through top electrodes TE.

While FIG. 4 shows that memory cells MC are formed in a single layer, it is to be noted that the present invention is not limited to such and the degree of integration of a variable resistance memory device may be significantly improved by forming memory cells MC in multiple layers through repeatedly performing the above-described fabrication processes.

As is apparent from the above descriptions, in the variable resistance memory device and the method for fabricating the same according to the embodiments of the present invention, by forming variable resistance layer patterns with a high aspect ratio, resistance dispersion of memory cells may be reduced while increasing a resistance difference between a high resistance state and a low resistance state of the respective memory cells. As a consequence, the operating voltage of the memory cells may be decreased and the number of memory cells per unit block may be increased to raise the degree of integration of a variable resistance memory device. Also, by preventing the variable resistance layer patterns from being damaged in an etching process, the reliability of the variable resistance memory device may be improved.

While the present invention has been described with respect to the specific embodiments, it will be apparent to those skilled in the art that, various changes and modifications may be made without departing from the spirit and scope of the invention as defined in the following claims.

What is claimed is:

1. A variable resistance memory device comprising:
first electrodes;
dielectric layer patterns vertically projecting from the first electrodes;
variable resistance layer patterns surrounding side surfaces of the dielectric layer patterns and connected with the first electrodes; and
second electrodes formed over the dielectric layer patterns and connected with the variable resistance layer patterns.

2. The variable resistance memory device of claim 1, wherein the first and second electrodes project sideward out of the dielectric layer patterns.

3. The variable resistance memory device of claim 1, further comprising:
a passivation layer contacting side surfaces of the variable resistance layer patterns.

4. The variable resistance memory device of claim 1, wherein the dielectric layer patterns have an aspect ratio larger than the first and second electrodes.

5. The variable resistance memory device of claim 1, wherein the dielectric layer patterns include at least any one selected from the group consisting of an oxide-based substance, a nitride-based substance and polysilicon.

6. The variable resistance memory device of claim 1, wherein portions of the variable resistance layer patterns which contact the first and second electrodes project.

7. The variable resistance memory device of claim 1, wherein the variable resistance layer patterns have electrical resistance changed by migration of oxygen vacancies or ions or phase change of a substance.

8. The variable resistance memory device of claim 1, further comprising:
first conductive lines connected with the first electrodes and extending in one direction; and
second conductive lines connected with the second electrodes and extending in a direction crossing with the first conductive lines.

9. The variable resistance memory device of claim 2, wherein the variable resistance layer patterns are formed on upper surfaces of projecting portions of the first electrodes and on lower surfaces of projection portions of the second electrodes.

10. A variable resistance memory device comprising:
first electrodes;
dielectric layer patterns vertically projecting from the first electrodes and having shapes of lines which extend in one direction;
variable resistance layer patterns disposed such that a pair of variable resistance layer patterns are arranged in parallel with each other and in both sides of each dielectric layer pattern, and connected with the first electrodes; and
second electrodes formed over the dielectric layer patterns and connected with the variable resistance layer patterns.

11. The variable resistance memory device of claim 10, wherein the first and second electrodes project sideward out of the dielectric layer patterns.

12. The variable resistance memory device of claim 10, further comprising:
a passivation layer contacting side surfaces of the variable resistance layer patterns.

13. The variable resistance memory device of claim 10, wherein the dielectric layer patterns have an aspect ratio larger than the first and second electrodes.

14. The variable resistance memory device of claim 10, wherein the dielectric layer patterns include at least any one selected from the group consisting of an oxide-based substance, a nitride-based substance and polysilicon.

15. The variable resistance memory device of claim 10, wherein portions of the variable resistance layer patterns which contact the first and second electrodes project.

16. The variable resistance memory device of claim 10, wherein the variable resistance layer patterns have electrical resistance changed by migration of oxygen vacancies or ions or phase change of a substance.

17. The variable resistance memory device of claim 10, further comprising:
first conductive lines connected with the first electrodes and extending in one direction; and
second conductive lines connected with the second electrodes and extending in a direction crossing with the first conductive lines.

18. The variable resistance memory device of claim 11, wherein the variable resistance layer patterns are formed on upper surfaces of projecting portions of the first electrodes and on lower surfaces of projection portions of the second electrodes.
